(19) United States
(12) Patent Application Publication
(10) Pub. No.: US 2024/0200407 A1
(43) Pub. Date: Jun. 20, 2024

(54) ELECTRIC BATTERY WORKOVER RIG

(71) Applicant: Moncla Workover & Drilling, LLC, Lafayette, LA (US)

(72) Inventors: Joel Broussard, Lafayette, LA (US); Matthew Moncla, Lafayette, LA (US); Jared Oehring, Cypress, TX (US); David Marc Moncla, Lafayette, LA (US)

(73) Assignee: Moncla Workover & Drilling, LLC, Lafayette, LA (US)

(21) Appl. No.: 18/068,934

(22) Filed: Dec. 20, 2022

Related U.S. Application Data
(60) Provisional application No. 63/257,817, filed on Oct. 20, 2021.

(51) Int. Cl. E21B 7/02; H05K 7/20

(52) U.S. Cl. CPC E21B 7/023; H05K 7/2089

(57) ABSTRACT

A workover rig including a retractable mast, a drawworks system, a drive system, and an electric power assembly. The retractable mast is configured to retract from an extended position into a retracted position for transportation. The drawworks system is configured to control movement of one or more objects suspended from a crown of the retractable mast in the extended position. The drive system is configured to control the drawworks system. The electric power assembly is configured to electrically power and control the drive system. The electric power assembly includes a cooling system.

### CROSS-REFERENCE TO RELATED APPLICATION

This application claims the benefit of and priority to U.S. Provisional Patent Application No. 63/257,817, filed on Oct. 20, 2021, which is incorporated herein by reference in its entirety.

### BACKGROUND

A workover rig is a mobile self-propelled rig or trailer mounted unit used to perform one or more remedial operations on a producing oil or gas well to restore or increase the well's production. For example, workover rigs may be used for deepening wells, plugging back, pulling and resetting liners, logging operations, swabbing operations, perforating tubing, lowering items into or retrieving items from the well (e.g., casing, tubing, rods, tools, pumps), running wireline cleaning, or repairing or replacing downhole equipment. When such service operations are necessary, a portable workover rig is often moved to the well site. While similar to a drilling rig, a workover rig is generally smaller. With workover activities, production must be stopped and the pressure in the reservoir contained (i.e., “killing” the well).

Some workover rigs have mobile vehicles or carriers, such as chassis carriers. Other workover rigs are trailer or skid mounted. A typical workover rig includes a collapsible mast or derrick which is hydraulically raised and lowered by means of hydraulic pistons. However, some derricks are cantilever style, which is similar to a drilling rig. The derrick or mast utilizes pulleys or block and tackle arrangements. A first heavy cable is wound around a mainline drum, with the free end of the cable connected over a crown block and run through the traveling block. By rotating the drum, the traveling block is raised or lowered with the mast as necessary. Traditional workover rigs are either single drum or double drum rigs. Some workover rigs include a second line wound around a sandline drum, with the second line running over the crown block and is then connected to an object (e.g., a swab mandrel) that is to be lowered into the wellbore to a selected depth. The second line is sometimes a conductive wireline with a logging instrument that permits logging. In many conventional workover rigs, the mainline drum and the sandline drum are usually run on the same engine, such as a system with diesel-powered engines and associated drive shafts, clutches, right angle gear boxes, chains, and sprockets or hydraulic motors. Some workover rigs have two engines. A typical workover rig includes a power system, a carrier, a drive system, a drawworks system, a mast and traveling system, a control system (e.g., hydraulic, air, and electrical), and accessories. Some workover rigs include a cross-mounted diesel engine that ties directly into a sprocket that powers an intermediate shaft or directly into the main drum.

### BRIEF DESCRIPTION OF THE DRAWING VIEWS

FIG. 1 is a schematic illustration of an electric battery workover rig including a single drum with a right-angle drive system.

FIG. 2 is a schematic illustration of an electric battery workover rig including a single drum with a direct drive system.

FIG. 3 is a schematic illustration of an electric battery workover rig including two drums with a right-angle drive system.

FIG. 4 is a schematic illustration of an electric battery workover rig including two drums with a direct drive system.

FIG. 5 is a schematic illustration of an electric battery workover rig mounted on a chassis.

FIG. 6 is a schematic illustration of a chassis mounted electric battery workover rig including an electrical power assembly.

FIG. 7 is a schematic illustration of one embodiment of an electrical power assembly for a chassis mounted electric battery workover rig.

FIG. 8 is a schematic illustration of an electric battery workover rig mounted on a chassis including a double drop transmission.

FIG. 9 is a side view of an electric battery workover rig including front and rear load beams and leveling jacks that are electrically controlled.

FIG. 10 is a schematic illustration of an electric workover rig with a peripheral energy storage unit and a peripheral power generation unit.

FIG. 11 is a schematic illustration of battery cells in an energy storage unit of the electric battery workover rig.

FIG. 12 is a schematic illustration of an energy storage unit of the electric battery workover rig.

FIG. 13 is a schematic illustration of an electric battery workover rig and a peripheral power generation unit.

FIG. 14 is a schematic illustration of an electric battery workover rig including a transformer and a peripheral power generation unit.

FIG. 15 is a schematic illustration of an electric battery workover rig including an energy storage unit with replaceable electric batteries.

FIG. 16 is a schematic illustration of an electric battery workover rig including an energy storage unit that is charged by a peripheral power generation unit.

FIG. 17 is a schematic illustration of a power generation unit and an energy storage unit mounted on a single platform.

### DETAILED DESCRIPTION OF SELECTED EMBODIMENTS

Disclosed herein is an electric battery workover rig including an electric power assembly configured to electrically power workover operations on the electric power assembly. In some embodiments, the electric battery workover rig includes a retractable mast configured to retract from an extended position into a retracted position for transportation, a drawworks system configured to control movement of one or more objects suspended from a crown of the retractable mast in the extended position, a drive system configured to control the drawworks system, and an electric power assembly configured to electrically power and control the drive system. The electric power assembly may include an energy storage unit configured to store electrical energy, a variable frequency drive electrically connected to the electrical motor, and one or more electric motors powered by the electrical energy stored in the energy storage unit and configured to control the drive system. The drawworks system may include a main drum and brake system controlled by the drive system and configured to control the movement of the one or more objects suspended from the crown of the retractable mast. In some embodiments (i.e., double drum embodiments), the drawworks system further includes a secondary drum and brake system.

The electric workover rig may be mounted on a truck or chassis and may include a cab. Alternatively, the electric workover rig may also be mounted on a trailer, a skid, or a platform. In addition, the major components of the electric workover rig may be mounted on a single unit or mounted on two or more separate units. For example, one embodiment of the electric workover rig may include an energy storage unit on a separate skid. Other embodiments of the electric workover rig may include a secondary, back-up energy storage unit on a separate skid. The electric workover rig may be used for any cased hole workover operations.

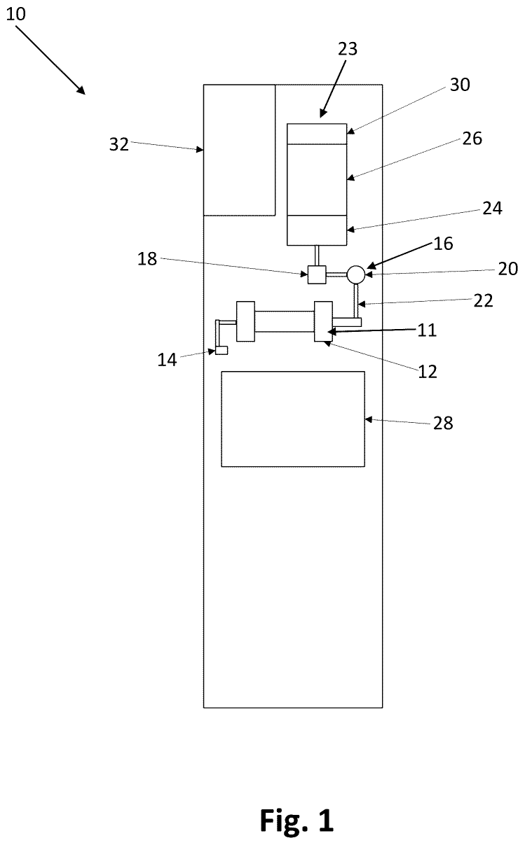

FIGS. 1-17 illustrate select embodiments of the electric battery workover rig.

FIG. 1 illustrates an electric battery workover rig 10 having a drawworks system 11 including a single main drum 12 and brake system 14. In this embodiment of the electric battery workover rig, drive system 16 includes a right-angle drive 18. The drive system 16 may also include a sprocket 20 coupled to the right-angle drive 18 and a chain 22. Instead of an engine and transmission or torque converter used on traditional workover rigs, this embodiment of the electric battery workover rig includes an electric power assembly 23 having an electric motor 24, a variable frequency drive (VFD) 26, and an energy storage unit 28. The electric motor 24 of the electric power assembly 23 is coupled to the main drum 12 of the drawworks system 11 via the right-angle drive 18, sprocket 20, and chain 22 of the drive system 16. Electric power assembly 23 may include cooling system 30 to provide cooling for the VFD 26 and electric motor 24. Cooling system 30 may utilize a liquid cooling system or an air cooling system. Electric battery workover rig 10 may further include cab 32.

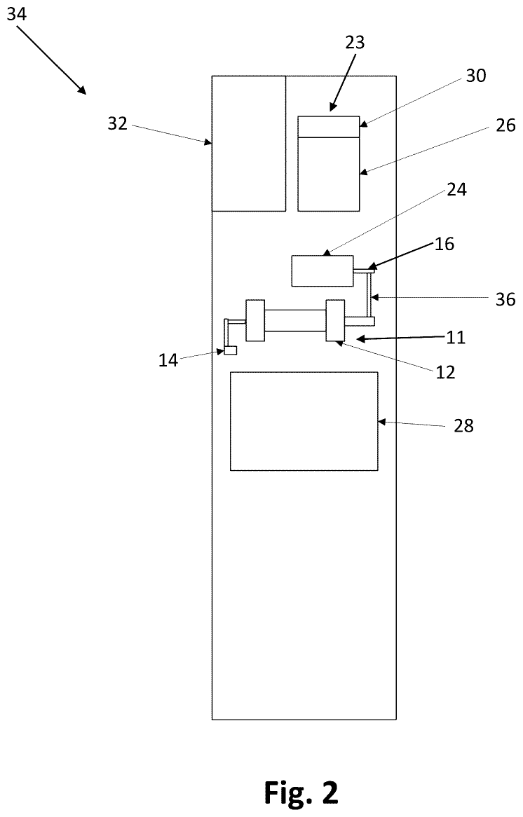

FIG. 2 illustrates another embodiment of an electric battery workover rig 34 having a drawworks system 11 including a single main drum 12 and brake system 14. In this embodiment, the drive system 16 includes a direct drive 36, which may include a chain, drive line, torque converter, or transmission. The one or more electric motors 24 of the electric power assembly 23 are coupled to the main drum 12 of the drawworks system 11 via the direct drive 36. Alternatively, the electric motor 24 may be directly coupled to the main drum 12.

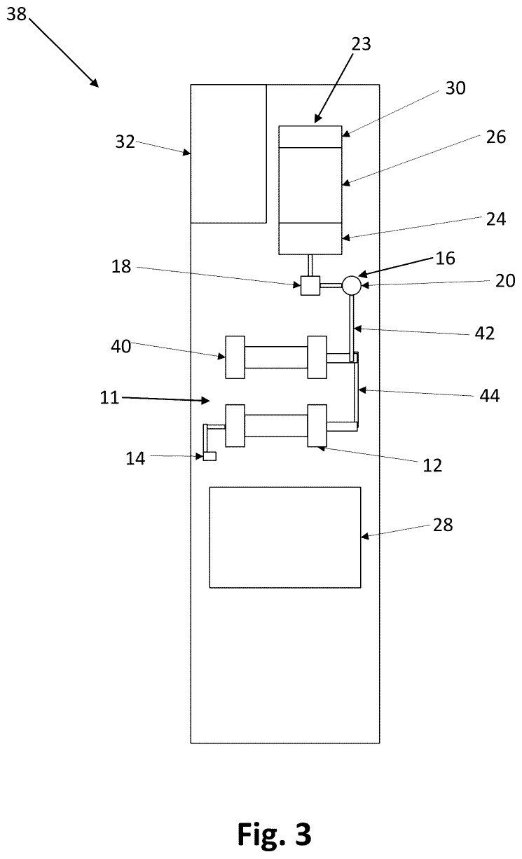

FIG. 3 illustrates an electric battery workover rig 38 having a drawworks system 11 including two drums, such as a main drum 12 and a swab or sand drum 40. In this embodiment, the drive system 16 includes a right-angle drive 18. The drive system 16 may also include a sprocket 20 coupled to the right-angle drive 18, a secondary chain 42 coupled to the sprocket 20 and the sand drum 40, and a main chain 44 coupled to the sand drum 40 and the main drum 12. The drawworks system 11 may include a single brake mechanism 14 for both the main drum 12 and the sand drum 40. Alternatively, the drawworks system 11 may include two brake mechanisms, with one coupled to the main drum 12 and the second coupled to the sand drum 40.

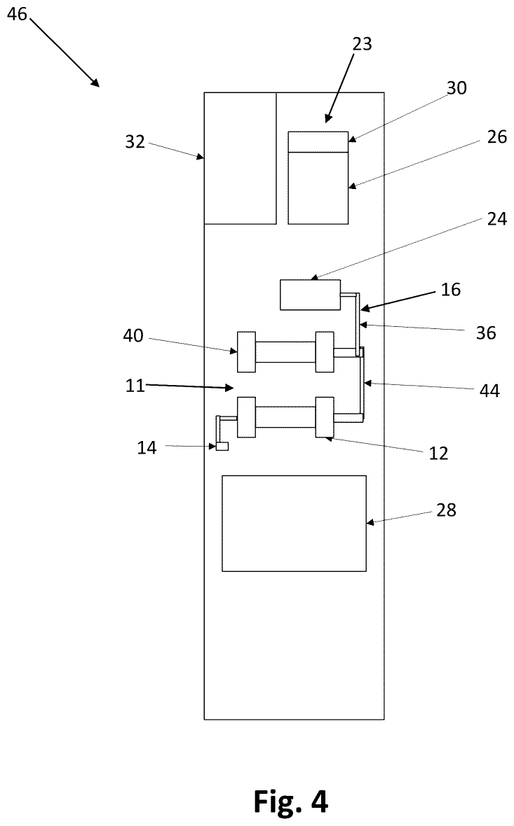

FIG. 4 illustrates another embodiment of an electric battery workover rig 46 having a drawworks system 11 including two drums, such as a main drum 12 and a sand or swab drum 40. In this embodiment, the drive system 16 includes a direct drive 36, which may include a chain, drive line, direct coupling, torque converter, transmission or other mechanical connection. The electric motor 24 of the electric power assembly 23 may turn the sand drum 40 of drawworks system 11 with the direct drive 36 of drive system 16, and sand drum 40 may turn main drum 12 with main chain 44 of drive system 16.

In the embodiments of the electric battery workover rig illustrated in FIGS. 1-4, the drums of the drawworks system require one or more brakes. The brakes may be hydromatic brakes, disk brakes, clutch brakes, or electric brakes. These illustrated embodiments are chassis mounted and each include a cab 32.

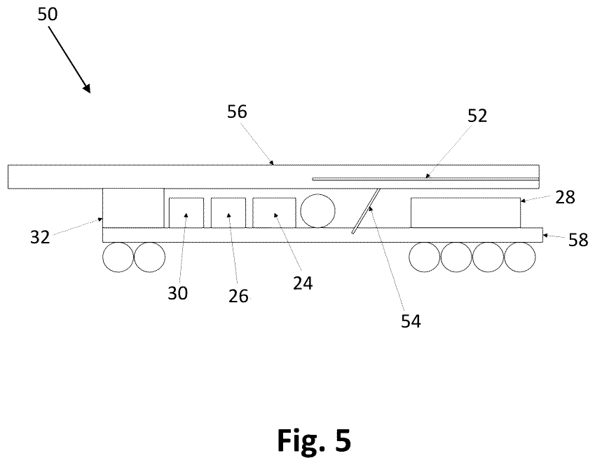

FIG. 5 shows a side view of a chassis mounted electric battery workover rig 50, which includes an energy storage unit 28. This electric battery workover rig 50 includes a scoping cylinder 52 and a lifting cylinder 54. The lifting cylinder 54 is used to stand the derrick or mast 56 upright from a retracted position (shown in FIG. 5) to an upright position. The scoping cylinder 52 is used to extend the derrick sections 56 into an extended position after they are in the upright position. The scoping cylinder 52 and lifting cylinder 54 may each be either hydraulic or electric powered. Electric battery workover rig 50 may be mounted on chassis platform 58.

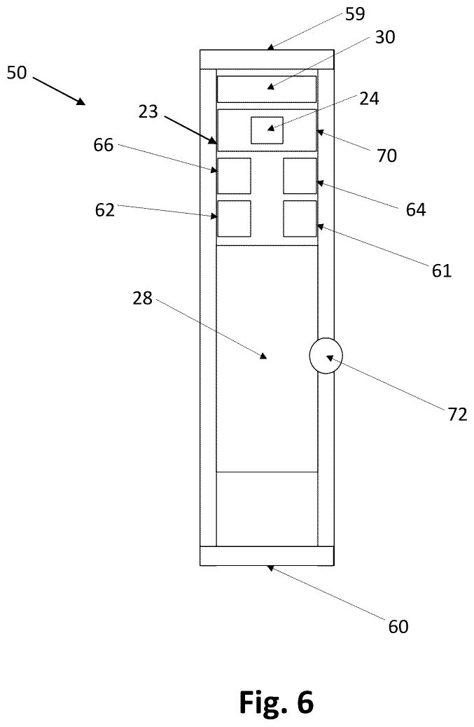

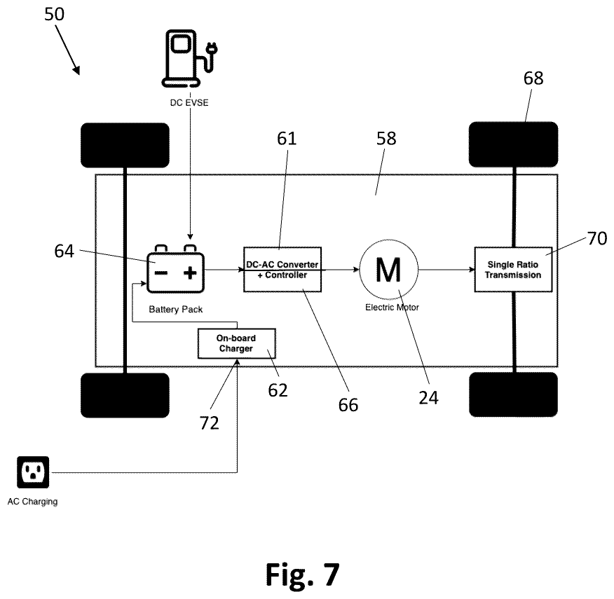

With reference to FIGS. 6 and 7, an electrical power assembly 23 is needed for transporting the electric battery workover rig 50 when it is mounted on a truck or chassis platform 58. Platform 58 may extend from front bumper 59 to rear bumper 60. Major components of the electrical power assembly 23 in this embodiment may include an energy storage unit 28, an electrical converter 61, one or more electric motors 24, and an on-board charger 62. The energy storage unit 28 or battery pack 64 may be formed of multiple lithium-ion cells or other battery cell chemistry. The energy storage unit 28 may store the electrical energy needed to run the vehicle. Battery packs 64 provide direct current (DC) output. The electric converter 61 may be formed of a DC-AC converter, a VFD, or a power inverter. The DC supplied by the battery pack 64 is converted to AC and supplied to the one or more electric motors 24. This power transfer is managed by a sophisticated motor control mechanism 66 (also referred to as power train electronic control unit), which controls the frequency and magnitude of the voltage supplied to the electric motor 24 in order to manage the speed and acceleration as per the driver's instructions communicated via acceleration and brake controls. The electric motor 24 converts electrical energy to mechanical energy, which is delivered to the wheels 68 via a single ratio transmission or other transmission 70. The electric vehicle may use motor generators that can also perform regeneration. The on-board charger 62 converts AC received through charge ports 72 to DC and controls the amount of current flowing into the battery pack 64.

In addition to these major components, the chassis mounted electric battery workover rig 50 may also include multiple hardware and software components in an electric vehicle (EV) power train. Electronic control units (ECUs) are software programs integrated with the powertrain components to help data exchange and processing. Several small ECUs in an EV may perform specific functions. The communication between different ECUs in a vehicle is commonly carried over CAN protocol or other common communication protocol. More examples of core ECUs that may be used in the chassis mounted electric battery workover rig 50 include: a battery management system, a DC-DC converter, a thermal management system, and/or a body control module. The battery management system (BMS) may continuously monitor the state of the battery and may take necessary measures in case of a malfunction. The BMS performs cell balancing to deliver maximum efficiency from the battery pack. It may communicate with other ECU's and sensors, as well as EVSEs, to control the charging input, check the current state of charge, and share data about battery specifications. The DC-DC converter may include a battery pack that delivers a fixed voltage, but the requirement of different accessory systems in the EV would vary. The DC-DC converter may help to distribute power to different systems by converting the output power from the battery pack to the expected level. After conversion, electric power is delivered to respective smaller ECUs via a wiring harness or wirelessly. The thermal management system may maintain optimum operating temperature range for powertrain components. The body control module (BCM) may supervise and control the functions of electronic accessories such as power windows, mirrors, security and vehicle access control.

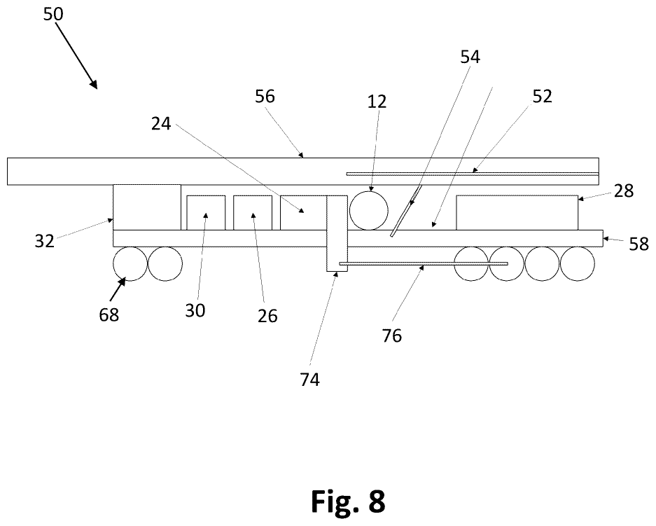

Referring now to FIG. 8, some embodiments of the chassis mounted electric battery workover rig 50 may include a double drop transmission 74. The double drop transmission 74 may be coupled to an electric motor 24 via a driveline, direct coupling, or any other coupling that allows the electric motor 24 to provide power to the traveling components or the rig components. In the illustrated embodiment, the drop transmission 74 is coupled to an electric motor 24 with a drive train 76 connecting to drive axles in the rear of the rig 50. In one embodiment, diesel engines may be replaced by a direct drive turbine connected to the transmission. In one embodiment, the electrical source is a separate unit that plugs into the electric battery workover rig 50 and charges the energy storage unit 28 electrically. In one embodiment, one or more diesel engines are used, but the hydraulics and pneumatics include electrical components. The engine provides power for both driving the platform 58 and as a prime mover for generators. In another embodiment, the one or more diesel engines are replaced by hydrogen fuel cells or all electric batteries or other energy source. The fuel for the generators may be gasoline, diesel, natural gas, hydrogen, propane, other combustible gas, or a blended engineered gas. All hydraulics and pneumatics are removed and replaced by fully electric components. In another embodiment, the hydraulics and pneumatics remain, becoming electric over hydraulic and/or electric over pneumatic. In one embodiment, the electric motors 24 are AC controlled by VFDs 26. In another embodiment, the electric motors 24 are DC.

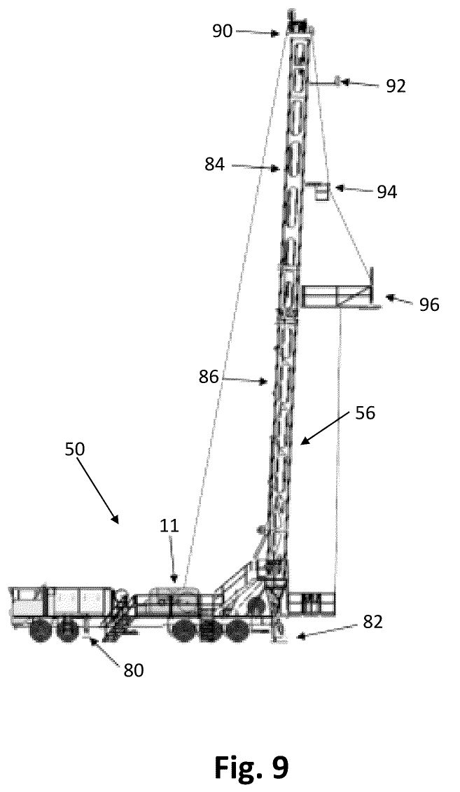

As shown in FIG. 9, the front load beam 80 and leveling jacks and the rear load beam 82 and leveling jacks may be controlled electronically or electric over hydraulic. In the illustrated embodiment of chassis mounted electric battery workover rig 50, retractable mast 56 is in an extended position with upper mast section 84 disposed beyond lower mast section 86. Crown 90 is disposed at an upper end of upper mast section 84. Fall arrest 92, rod basket 94, and tubing board 96 may all be supported by retractable mast 56.

Table 1 below shows hoist capacities for various HP. The engine can be replaced by a battery with electric DC motors. It can also be replaced by AC motors with VFDs.

TABLE 1

| | | Nominal Engine | | | Depth Capacity | | Depth Capacity | |
|---|---|---|---|---|---|---|---|---|
| Hoist Capacity | | Power | | Mast. | 2⅞ tubing | | 4½ Drill Pipe | |
| Tons | (Tonnes) | HP | (KW) | Model No | ft | (m) | ft | (m) |
| 62.5 | (57) | 300 | (224) | 72′-125 | 10,000′ | (3,049) | | |
| 105 | (95) | 425 | (317) | 102′-200 | 17,000′ | (5,183) | 5,000′ | (1,524) |
| 125 | (113) | 525 | (392) | 104′-250 | 20,000′ | (6,098) | 6,500′ | (1,982) |
| 150 | (136) | | | 108′-250 | | | | |
| | | | | 108′-300 | | | | |
| 150 | (136) | 630 | (470) | 108′-300 | 22,000′ | (6,707) | 8,000′ | (2,439) |
| 175 | (159) | | | 112′-300 | | | | |
| | | | | 117′-350 | | | | |
| 175 | (159) | 775 | (578) | 117′-350 | 25,000′ | (7,622) | 10,000′ | (3,040) |
| 200 | (181) | | | 117′-400 | | | | |

Table 2 below includes configurations for different brakes for single line pull.

TABLE 2

| Single | Drum Dia. | | No. | Brake | Degree | | Effec. Brake | | |
|---|---|---|---|---|---|---|---|---|---|
| Line Pull | Inches | Drum | Hoist | Size in. | of | Brake | Area sq. in. | Auxiliary | Sandline |
| (on Lebus) | (mm) | Clutch | Speeds | (mm) | Wrap | Cooling | (sq. m) | Brake | Cap./Size |
| 35,500# | 17″ | P0224 | 5 | 38″ × 10″ | 330 | Splash | 2279 sq. in. | * | 8,230′ |
| | (434) | | | (970 mm × | | | (1.47 sq. m) | | of 9/16 |
| | | | | 255 mm) | | | | | |
| 40,000# | 19⅝″ | P0224 | 5 | 42″ × 12″ | 330 | Splash or | 3054 sq. in. | * | 12,000′ |
| | (498) | | | (1067 mm × | | Circulating | (1.97 sq. m) | | of 9/16 |
| | | | | 305 mm) | | | | | |
| 40,000# | 19⅝″ | P0224 | 5 | 42″ × 12″ | 330 | Circulating | 3054 sq. in. | * | 14,500′ |
| | (498) | | | (1067 mm × | | | (1.97 sq. m) | | of 9/16 |
| | | | | 305 mm) | | | | | |

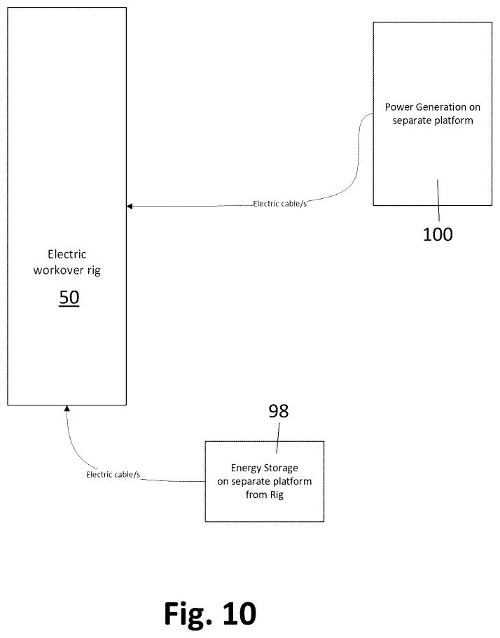

Referring now to FIG. 10, the electric battery workover rig 50 includes an energy storage system or battery power storage 98. This energy storage system 98 may be mounted on the workover rig 50 or may be mounted on a separate platform near the workover rig 50. Similarly, power generation components 100 may be mounted on a separate platform near the workover rig 50.

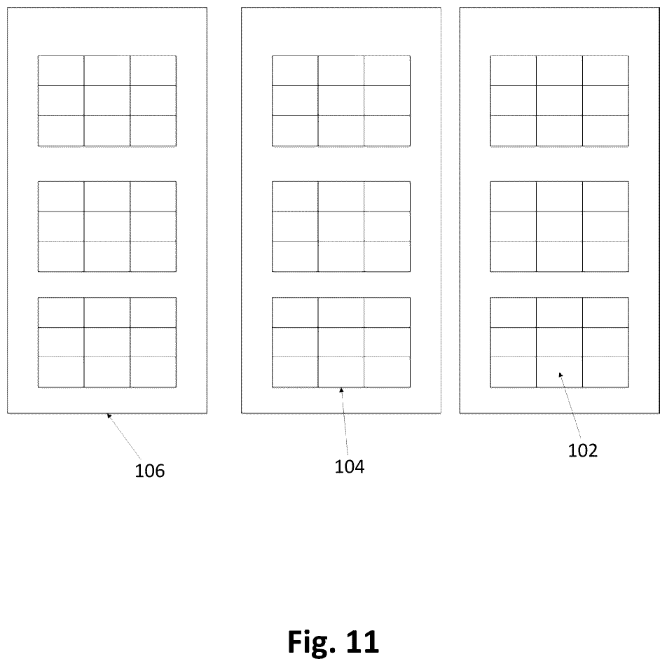

FIG. 11 illustrates one embodiment of battery cells 102 used for energy storage on the electric battery workover rig. These battery cells 102 may be grouped together to form a battery module 104. The battery modules 104 may then be grouped together to form a rack 106. Multiple racks 106 may be grouped to provide the required electric power and energy needed for the electric battery workover rig. The electric battery may provide power for both workover operation and chassis traveling operations of the electric battery workover rig 50.

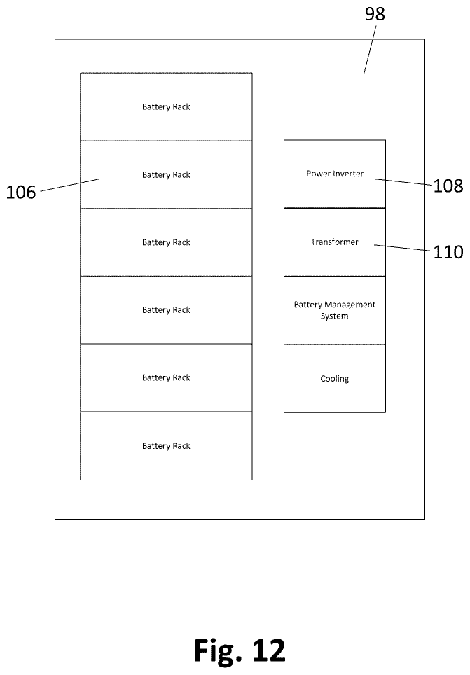

With reference to FIG. 12, an energy storage system (ESS) 98 may be composed of one or more racks 106 with a power inverter system 108. The power inverter system 108 may allow the direct current electricity to be converted into alternating current electricity. The ESS may also have a transformer system 110. This allows the battery system to be at one voltage while the power generation may be at another often higher voltage. For example, the DC circuit may be 1,000 V while the power generation may be at 13.8 kV. If necessary, another transformer may transform the electricity from the power generation voltage to the working voltage need for workover rig and chassis traveling modes, which may occur at 480V, 600V, 690V, or any other voltage.

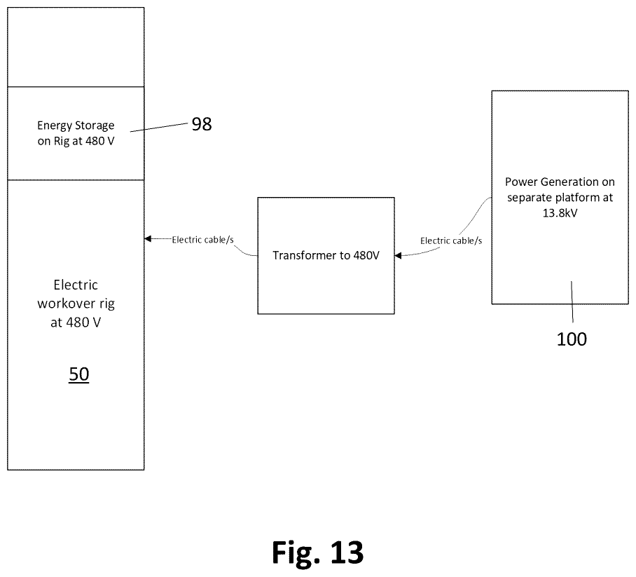

In the embodiment illustrated in FIG. 13, the working voltage for the electric battery workover rig 50 and the batteries of the energy storage system 98 are the same voltage. This allows for only one transformer going from the workover rig 50 to the power generation platform 100. Voltages may be different from the 480V shown in FIG. 13.

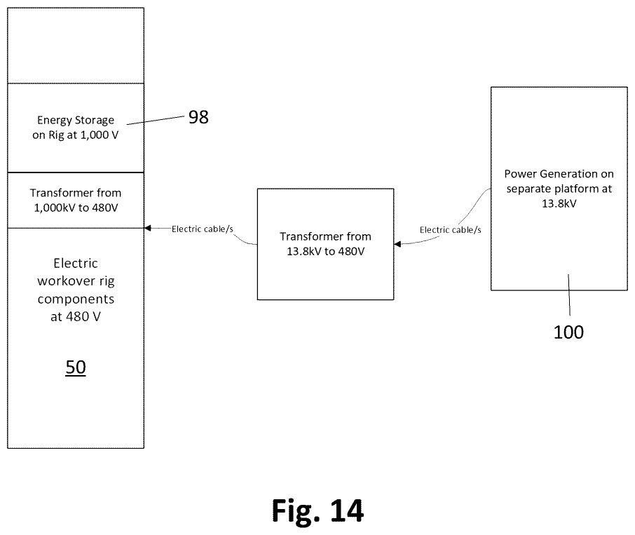

In other embodiments, such as the embodiment illustrated in FIG. 14, the working voltage for the components of the electric battery workover rig 50 and the batteries of the energy storage system 98 are of different voltages. In these embodiments, an additional transformer is needed for each level of needed voltage. A multi-tap transformer may also be used that outputs multiple voltages. Transformers may be mounted on the same platform as the electric battery workover rig 50, on a separate platform, or a combination thereof.

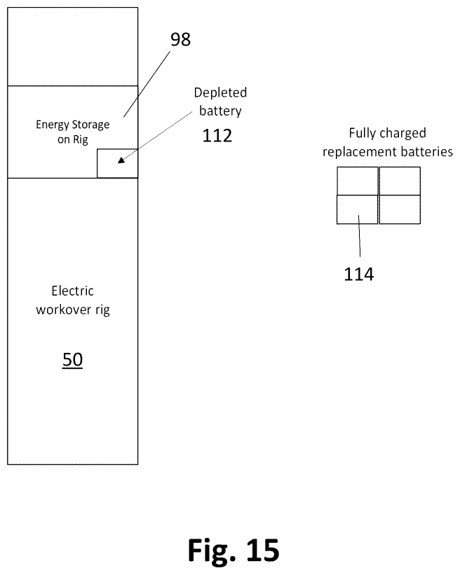

FIG. 15 illustrates an embodiment of the electric battery workover rig 50 in which the batteries of the energy storage system 98 are replaceable. In this embodiment, the batteries 112 that are low or nearly depleted may be removed and replaced with batteries 114 that are fully charged. The removed batteries may then be charged and stored for future use.

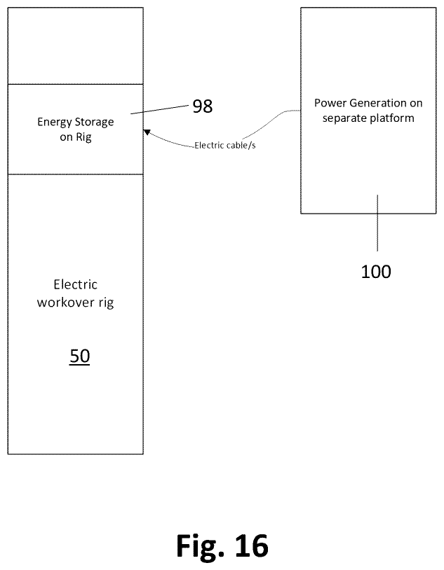

In some embodiments, such as the embodiment illustrated in FIG. 16, the energy storage system 98 may be mounted on the electric battery workover rig 50. In this embodiment, the energy storage system 98 may be charged by a cable and plug connection to a power generation source 100 on a separate platform.

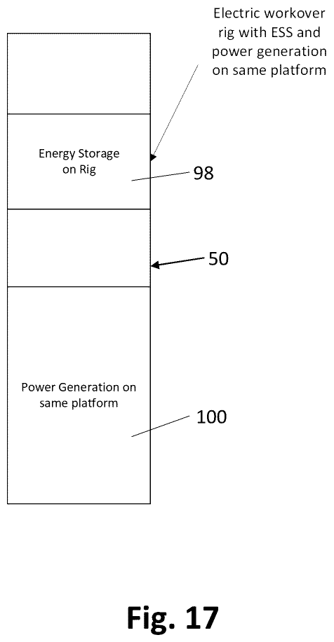

In other embodiments, such as the embodiment illustrated in FIG. 17, the power generation 100 and energy storage system 98 are both mounted on the electric battery workover rig 50.

In all embodiments, power generation may be from any electrical source including one or more of a turbine generator, diesel generator, reciprocating engine generator, fuel cell, solar farm, wind farm, energy storage system, microgrid, grid power, dual fuel engine generators, or any other electrical power source. Fuel for the power generation may include diesel, natural gas, propane, gasoline, hydrogen, engineered combined gas (such as a hydrogen-natural gas blend), or any combustible liquid and/or combustible gas source.

Each device described in this disclosure may include any combination of the described components, features, and/or functions of each of the individual device embodiments. Each method described in this disclosure may include any combination of the described steps in any order, including the absence of certain described steps and combinations of steps used in separate embodiments. Any range of numeric values disclosed herein includes any subrange therein. “Plurality” means two or more.

While preferred embodiments have been described, it is to be understood that the embodiments are illustrative only and that the scope of the invention is to be defined solely by the appended claims when accorded a full range of equivalents, many variations and modifications naturally occurring to those skilled in the art from a review hereof.

We claim:

1. A workover rig, comprising:
a retractable mast configured to retract from an extended position into a retracted position for transportation;
a drawworks system configured to control movement of one or more objects suspended from a crown of the retractable mast in the extended position;
a drive system configured to control the drawworks system; and
an electric power assembly configured to electrically power and control the drive system, wherein the electric power assembly includes a cooling system.

2. The workover rig of claim 1, wherein the electric power assembly is configured to electrically power and control the drive system without any external electric power source.

3. The workover rig of claim 1, wherein the electric power assembly includes:
an energy storage unit configured to store electrical energy;
a variable frequency drive electrically connected to the electric motor;
an electric motor powered by the electrical energy stored in the energy storage unit and configured to control the drive system,
wherein the cooling system of the electric power assembly is configured to cool the variable frequency drive and the electric motor.

4. The workover rig of claim 3, wherein the energy storage unit includes battery cells.

5. The workover rig of claim 3, wherein the drawworks system includes:
a main drum and brake system controlled by the drive system and configured to control the movement of the one or more objects suspended from the crown of the retractable mast.

6. The workover rig of claim 5, wherein the drive system includes a right-angle drive.

7. The workover rig of claim 5, wherein the drive system includes a direct drive.

8. The workover rig of claim 5, wherein the drawworks system further includes a secondary drum and brake system controlled by the drive system and configured to control the movement of a secondary object suspended from the crown of the retractable mast in the extended position.

9. The workover rig of claim 8, wherein the drive system includes a right-angle drive.

10. The workover rig of claim 8, wherein the drive system includes a direct drive.

11. The workover rig of claim 1, wherein the workover rig is contained on a single unit.

12. The workover rig of claim 1, wherein the workover rig includes at least two separate units, wherein each of the two separate units are mounted on a truck, chassis, trailer, skid, or platform.

13. The workover rig of claim 12, wherein the retractable mast, the drawworks system, the drive system, and an electric motor of the electric power assembly are mounted on a first unit; wherein an energy storage unit of the electric power assembly is mounted on a second unit; wherein the energy storage unit on the second unit is configured to store electrical energy.

14. The workover rig of claim 13, wherein the energy storage unit on the second unit is a primary energy storage unit.

15. The workover rig of claim 13, wherein a primary energy storage unit is mounted on the first unit; and wherein the energy storage unit on the second unit is a back-up energy storage unit.

16. The workover rig of claim 4, wherein the workover rig is mounted on a truck or chassis.

17. The workover rig of claim 16, wherein travel of the truck or chassis is powered by the electrical energy stored in the energy storage unit.

18. The workover rig of claim 1, wherein the workover rig is mounted on a trailer, skid, or platform.
